(19) United States
(12) Patent Application Publication
(10) Pub. No.: US 2009/0115068 A1
(43) Pub. Date: May 7, 2009

(54) Semiconductor Device and Method of Manufacturing the Same

(76) Inventor: Jeong Yel Jang, Eumseong-gun (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/251,726

(22) Filed: Oct. 15, 2008

(30) Foreign Application Priority Data
Nov. 6, 2007 (KR) 10-2007-0112876

(51) Int. Cl. H01L 23/48; H01L 21/4763

(52) U.S. Cl. 257/774; 438/618; 257/E23.01; 257/E21.495

(57) ABSTRACT

Provided are a semiconductor device and a method of manufacturing the same. In the method, a metal interconnection can be formed on a substrate. A dielectric can be formed on the metal interconnection. A photoresist pattern can be formed on the dielectric. The dielectric can be etched using the photoresist pattern as an etch mask to form a dense region of contact holes exposing the metal interconnection and dummy patterns surrounding the region of contact holes. In the semiconductor device, the dummy patterns are disposed around the dense contact holes to minimize a difference between etching rates of the contact holes, thereby inhibiting an etching defect such as an under-etch or over-etch defect.

### CROSS-REFERENCE TO RELATED APPLICATION

The present application claims the benefit under 35 U.S.C. §119 of Korean Patent Application No. 10-2007-0112876, filed Nov. 6, 2007, which is hereby incorporated by reference in its entirety.

### BACKGROUND

With the fast penetration of information media such as computers into the market, semiconductor devices are being remarkably developed in recent years. In terms of the function, the semiconductor devices are required to meet mass storage capacity and data-processing ability, as well as high-speed operation. Responding to such requirements, manufacturing technologies for semiconductor devices are being rapidly developed with a focus on increasing integration, reliability, and response speed.

A photolithography process is necessary for fabricating a semiconductor device. The photolithography process includes the following processes: uniformly coating a photoresist layer on a wafer; performing an exposure process on the photoresist layer using a photomask having a predetermined lay-out; and developing the exposed photoresist layer to form a pattern having the shape determined by the predetermined lay-out.

The photolithography process is performed to form a photoresist pattern. The photoresist pattern can be used, for example, as a contact or metal pattern etch mask, and a lower metal layer or dielectric is etched to form a contact hole in a metal pattern or the dielectric using the photoresist pattern as the etch mask.

In development of logic and flash semiconductor products designed using a 90 nm or less design rule, a via hole having a hole size of about 130 nm or less is formed in a via hole etching process during a Back End of the Line (BEOL) process. Thus, a region in which the via hole opens is defined as about 5% or less of a wafer surface, and remaining regions are covered by a photoresist serving as a mask.

As a result, in the via hole etching process using plasma, reaction between fluorocarbon radicals and the photoresist and reaction by-products (polymer) generated by the reaction therebetween act as important parameters in the via hole etching process in addition to the kinds and amount of reaction by-products generated by reaction between the fluorocarbon radicals and an oxide film that is an etch target layer.

FIGS. 1 and 2 are cross-sectional views illustrating dense contact holes of a related art semiconductor device.

FIG. 1 is a cross-sectional view illustrating contact holes in which portions thereof are under-etched in a related art semiconductor device. FIG. 2 is a cross-sectional view illustrating contact holes in which portions thereof are over-etched in a related art semiconductor device.

Referring to FIGS. 1 and 2, a plurality of contact holes 30 is formed in a dielectric 20 disposed on a lower substrate 10.

In a BEOL process of a logic device designed using a 90 nm or less design rule, to form the contact holes 30 connecting a lower metal interconnection to an upper metal interconnection, an argon fluoride (ArF) light source having a wavelength of 193 nm is used as a light source for a photolithography process because a hole size of each of the contact holes 30 is very small (about 130 nm or less). Accordingly, a photoresist pattern serving as a mask during an etching process is formed.

A black diamond (BD) or a fluorinated silicate glass (FSG), which are low-k materials including carbon and fluorine, are often used as the dielectric 20 in order to reduce a resistance capacitance (RC) delay between the metal interconnections. However, these materials produce a large amount of CxFy-based reaction by-products during the etching process compared to related art tetraethylorthosilicate (TEOS) and undoped spin-on-glass (USG) layers.

The reaction by-products accumulate in the contact holes 30 during the contact hole etching process, interrupting the etching process.

Referring to FIG. 1, in the process of forming the plurality of contact holes, the lower substrate 10 may be properly exposed by the contact holes 30 formed on a middle region. However, an edge region of the lower substrate 10 is not properly exposed by the contact holes 30 formed thereon because the dielectric 20 is not completely etched due to the reaction by-products generated during the etching process, thereby causing an under-etch defect K1.

Referring to FIG. 2, in the process of forming the plurality of contact holes, to properly expose the edge region of the lower substrate 10 by the contact holes 30 formed thereon, the middle region of the lower substrate 10 is over-etched, thereby causing an over-etch defect K2.

### BRIEF SUMMARY

Embodiments of the present invention relate to substantially uniform etching for active regions of a wafer. According to an embodiment, a semiconductor device is provided in which dummy patterns are disposed around dense contact holes to obtain substantially uniform etching rates of the contact holes. A method of manufacturing the same is also provided.

In one embodiment, a semiconductor device can comprise: a metal interconnection on a substrate; and a dielectric covering the metal interconnection, the dielectric comprising contact holes exposing a portion of the metal interconnection and dummy patterns surrounding the contact holes.

In another embodiment, a method of manufacturing a semiconductor device can comprise: forming a metal interconnection on a substrate; forming a dielectric on the metal interconnection; forming a photoresist pattern on the dielectric; and etching the dielectric using the photoresist pattern as an etch mask to form contact holes exposing the metal interconnection and dummy patterns surrounding the contact holes.

In a semiconductor device according to an embodiment, dummy patterns can be disposed around dense contact holes to minimize a difference between etching rates of the contact holes, thereby inhibiting an etching defect such as an under-etch or an over-etch.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating contact holes in which portions thereof are under-etched in a related art semiconductor device.

FIG. 2 is a cross-sectional view illustrating contact holes in which portions thereof are over-etched in a related art semiconductor device.

FIG. 3 is a plan view illustrating dense contact holes of a semiconductor device according to an embodiment.

FIG. 4 is a cross-sectional view taken along line I-I′ of FIG. 3.

FIGS. 5 to 9 are cross-sectional views illustrating a process of forming contact holes of a semiconductor device according to an embodiment.

FIG. 10 is a partial plan view of a semiconductor device according to another embodiment.

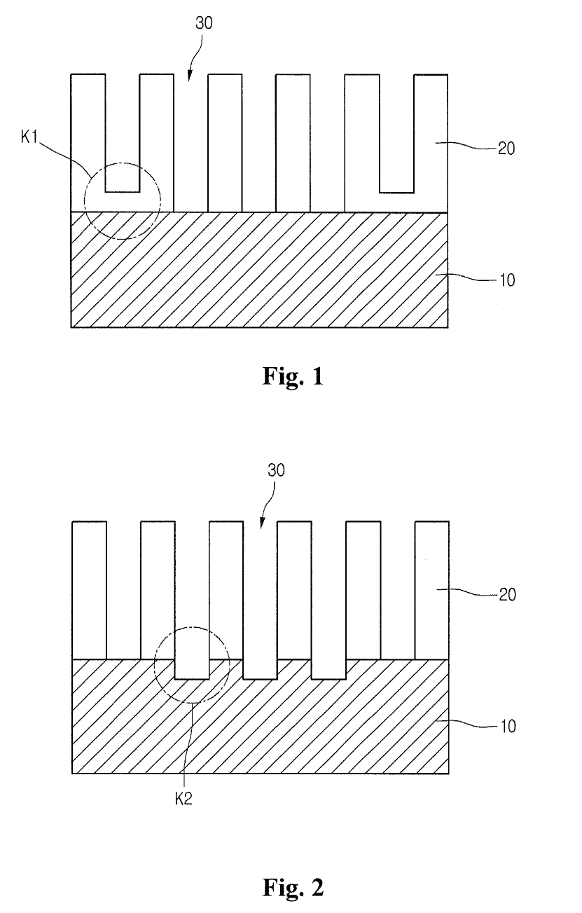

### DETAILED DESCRIPTION

Hereinafter, a semiconductor device and a method of manufacturing the same according to an embodiment will be described in detail with reference to the accompanying drawings. The invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing, and will fully convey the concept of the invention to those skilled in the art.

In addition, it will also be understood that when the terms like “first”, and “second” are used to describe members, the members are not limited by these terms. For example, a plurality of members may be provided. Therefore, when the terms like “first”, and “second” are used, it will be apparent that the plurality of members may be provided. In addition, the terms “first” and “second” can be selectively or exchangeably used for the members. In the figures, a dimension of each of elements may be exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted. Also, in the descriptions of embodiments, it will be understood that when a layer (or film), a region, a pattern, or a structure is referred to as being ‘on/above/over/upper’ substrate, each layer (or film), a region, a pad, or patterns, it can be directly on substrate each layer (or film), the region, the pad, or the patterns, or intervening layers may also be present. Further, it will be understood that when a layer is referred to as being ‘under/below/lower’ each layer (film), the region, the pattern, or the structure, it can be directly under another layer (film), another region, another pad, or another patterns, or one or more intervening layers may also be present. Therefore, meaning thereof should be judged according to the spirit of the present disclosure.

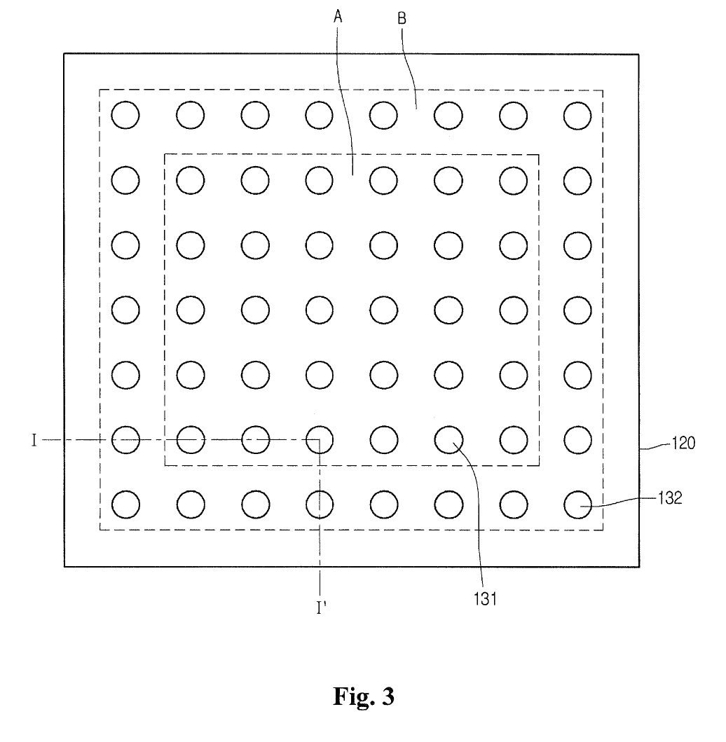

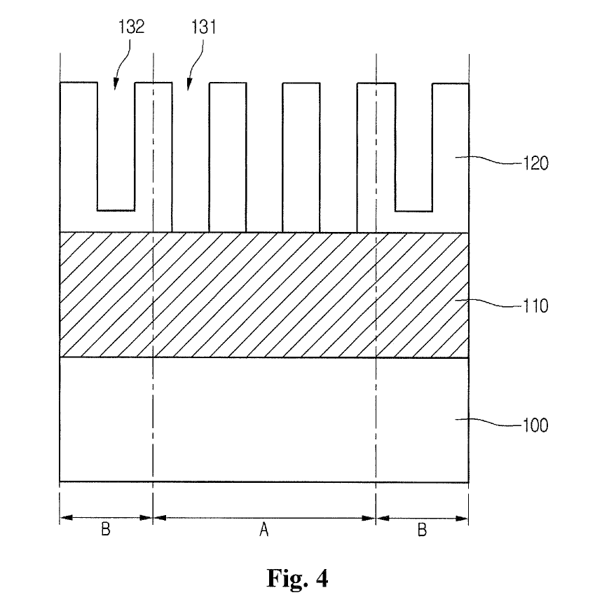

FIG. 3 is a plan view illustrating dense contact holes of a semiconductor device according to an embodiment, and FIG. 4 is a cross-sectional view taken along line I-I′ of FIG. 3.

Referring to FIGS. 3 and 4, a metal interconnection 110 can be disposed on a semiconductor substrate 100. A dielectric 120 can be disposed on the semiconductor substrate 100 including the metal interconnection 110.

The dielectric 120 includes a contact hole region A and a dummy region B surrounding the contact hole region A.

Although not shown, the semiconductor device can include structures such as transistors, additional metal interconnections, and additional dielectrics.

The dielectric 120 can include a plurality of densely formed contact holes 131 disposed in the contact hole region A. The contact holes 131 expose a portion of the metal interconnection 110.

Dummy contact holes 132 surrounding the contact holes 131 are disposed in the dummy region B of the dielectric 120.

The dummy contact holes 132 can have the same size and distance from each other as those of the contact holes 131.

Each of the dummy contact holes 132 and the contact holes 131 can have a square or circular shape.

Although the dummy contact holes 132 are not electrically connected to the lower metal interconnection 110, the dummy contact holes 132 are disposed in the dielectric 120. The dummy contact 132 uniformly distributes the concentration of etching reaction by-products and compensates a difference between etching rates caused according to positions of the contact holes 131 during a contact hole etching process.

The dummy contact holes 132 can be disposed along a single line on the outside of the contact hole region A. The dummy contact holes 132 include at least three or more contact holes 132.

Since the dummy contact holes 132 are disposed around the contact holes 131 at an edge region of the dense contact hole area, an under-etch can occur due to an unbalance of the etching reaction by-products. Thus, the metal interconnection 110 or a lower substrate below the dummy contact holes 132 may not be exposed.

In a BEOL process of a logic device designed using about 90 nm or less design rule, when the contact holes 30 connecting a lower metal interconnection to an upper metal interconnection are formed, an argon fluoride (ArF) light source having a wavelength of 193 nm is used as a light source to form a photoresist pattern because a hole size of each of the contact holes 131 is very small (about 130 nm or less). The photoresist pattern then serves as a mask during a subsequent etching process.

Black diamond (BD) or fluorinated silicate glass (FSG), which are low-k materials including carbon and fluorine, can be used as the dielectric 120 in order to reduce a RC delay between the metal interconnections. As noted above, these materials produce a large amount of CxFy-based reaction by-products during the etching process compared to related art tetraethylorthosilicate (TEOS) and undoped spin-on-glass (USG) layers.

The reaction by-products may accumulate in certain ones of the contact holes during the contact hole etching process to interrupt the etching process. However, since the dummy contact holes 132 are disposed at edge regions of the dense contact hole area, the etching reaction by-products may be uniformly distributed in the contact hole region A while not being uniformly distributed in the dummy region B.

Therefore, the contact holes 131 disposed in the contact hole region A can have the same etch rate to inhibit the under-etch or over-etch defects from being generated.

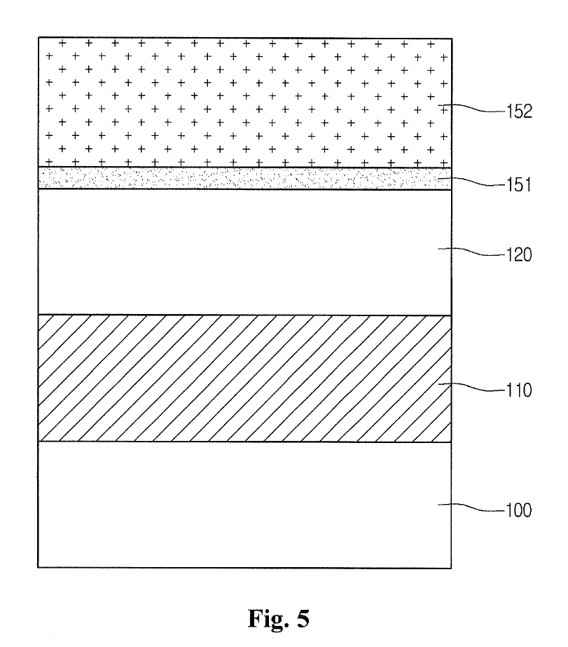

FIGS. 5 to 9 are cross-sectional views illustrating a process of forming contact holes of a semiconductor device according to an embodiment.

Referring to FIG. 5, a metal interconnection 110 can be formed on a semiconductor substrate 100.

A dielectric 120 can be formed on the metal interconnection 110.

In certain embodiments, BD or FSG can be used as the dielectric 120.

An anti-reflection layer 151 and a photoresist layer 152 can be formed on the dielectric 120.

The anti-reflection layer 151 can be included to inhibit defect patterns from being generated by reflected light during an exposure process of the photoresist layer 152.

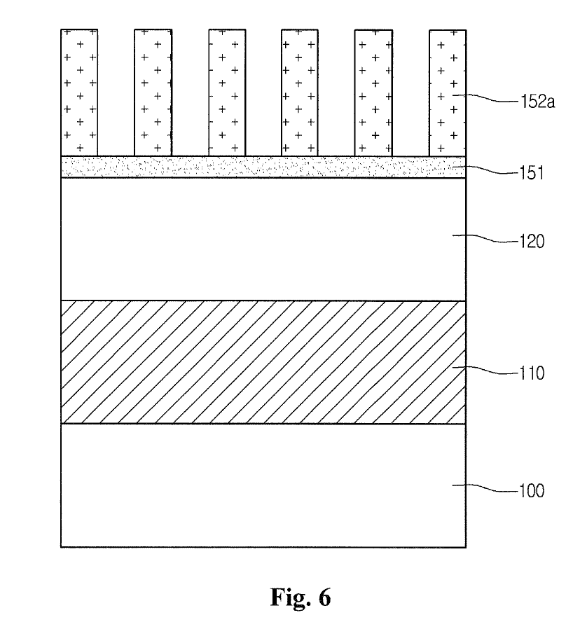

Referring to FIG. 6, the photoresist layer 152 can be selectively exposed and developed to form a photoresist pattern 152a exposing a portion of the anti-reflection layer 151. The photoresist pattern 152a can be a pattern for forming contacts that will electrically connect the metal interconnection 110 below the dielectric 120 to an upper metal interconnection (not shown).

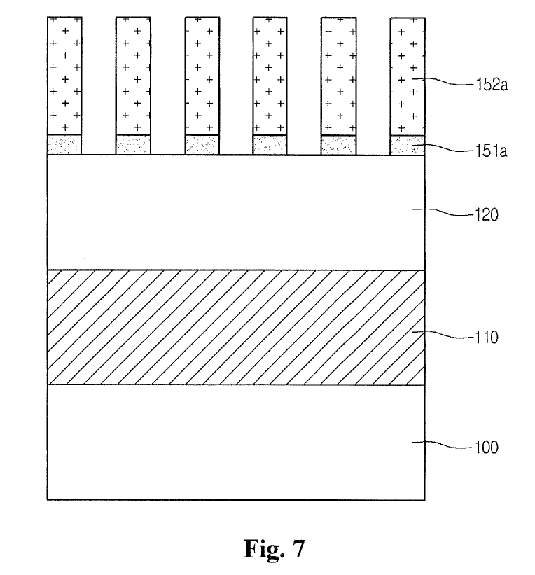

Referring to FIG. 7, the anti-reflection layer 151 can be etched using the photoresist pattern 152a as an etch mask to form an anti-reflection layer pattern 151a.

In one embodiment, the anti-reflection layer can be etched under the following etching conditions. A chamber pressure of from about 70 mT to about 110 mT, a source power of from about 100 W to about 500 W, a bias power of from about 0 W to about 100 W, a flow rate of argon (Ar) of from about 200 sccm to about 400 sccm, a flow rate of CF₄ of from about 10 sccm to about 50 sccm, and a flow rate of O₂ of from about 2 sccm to about 10 sccm.

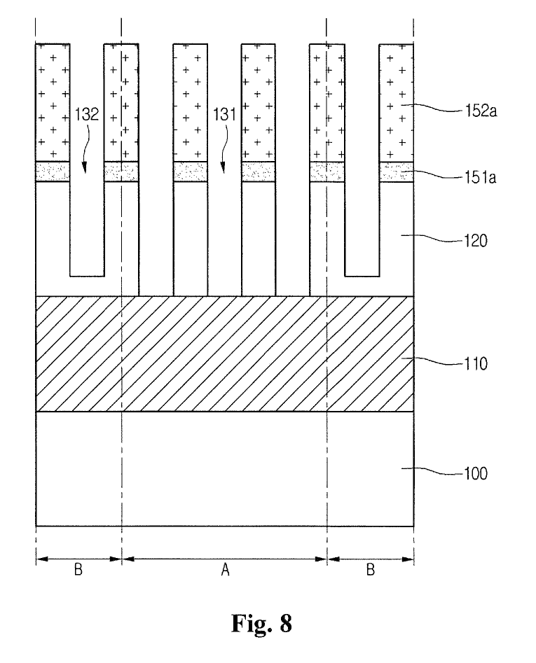

Referring to FIG. 8, the dielectric 130 can be etched using the anti-reflection layer 151a and the photoresist pattern 152a as an etch mask.

The dielectric etching process can include a main etching process and an over etching process.

In one embodiment, the main etching process can be performed under the following etching conditions. A chamber pressure of from about 90 mT to about 120 mT, a source power of from about 200 W to about 800 W, a bias power of from about 1000 W to about 1500 W, a flow rate of Ar of from about 150 sccm to about 350 sccm, a flow rate of C₄F₆ of from about 1 sccm to about 10 seem, a flow rate of CH₂F₂ of from about 1 sccm to about 5 sccm, a flow rate of O₂ of from about 1 sccm to about 5 sccm, and a flow rate of N₂ of from about 100 sccm to about 250 sccm.

In a further embodiment, an over etching process can be performed under the following etching conditions. A chamber pressure of from about 100 mT to about 130 mT, a source power of from about 300 W to about 700 W, a bias power of from about 800 W to about 1500 W, a flow rate of Ar of from about 200 sccm to about 300 sccm, a flow rate of C₄F₆ of from about 1 sccm to about 5 sccm, and a flow rate of N₂ of from about 80 sccm to about 150 sccm.

In the over etching process, the C₄F₆:N₂ flow ratio can be adjusted to about 30:1 or less to adjust an amount of the reaction by-products.

The main etching process and the over etching process can be performed to form contact holes 131 and dummy holes 132 in the dielectric 120.

The contact holes 131 can be densely disposed, and the dummy contact holes 132 surround the densely disposed contact holes 132.

The dummy contact holes 132 are not substantially connected to the lower metal interconnection 110. That is, the dummy contact holes 132 can be formed above the lower metal interconnection 110 while not fully exposing the lower metal interconnection 110.

A distance between the contact holes 131 may range from about 100 nm to about 140 nm, a distance between any one of each of the contact holes 131 and a dummy contact hole 132 adjacent to the contact hole 131 can range from about 100 nm to about 140 nm.

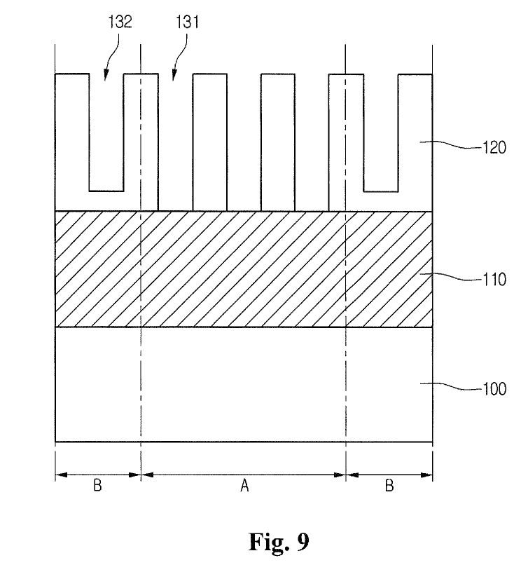

Referring to FIG. 9, the photoresist pattern 152a and the anti-reflection layer pattern 151a can be removed to expose the dielectric 120.

Accordingly, the dielectric 120 includes the densely formed contact holes 131 and the dummy contact holes 132 surrounding the contact holes 131.

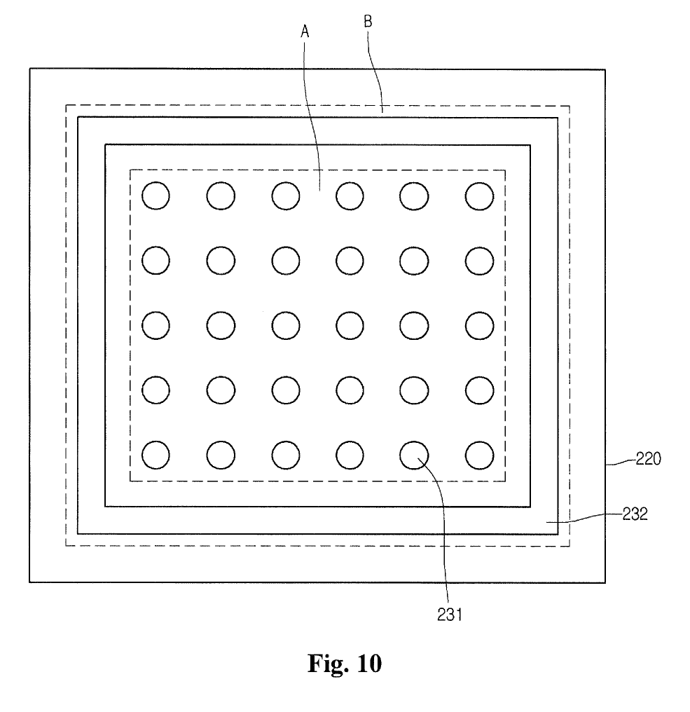

FIG. 10 is a partial plan view of a semiconductor device according to another embodiment.

Referring to FIG. 10, a dielectric 220 can be disposed on a semiconductor substrate. The dielectric 220 includes a contact hole region A and a dummy region B.

The dielectric 220 includes a plurality of contact holes 231 arranged by predetermined distances in the contact hole region A. In addition, the dielectric 220 can include a dummy line 232 surrounding the contact holes 231 in the dummy region B.

The dummy line 332 may surround the contact hole region A to provide a closed-loop structure, or a portion of the dummy line 332 may be opened (or not etched) to provide a line pattern structure.

When the dielectric 220 is etched to form the contact holes 231 and the dummy line 232, the etching reaction by-products are produced. The etching reaction by-products may be uniformly distributed in the contact hole region A while not being uniformly distributed in the dummy region B.

Therefore, the contact holes 131 disposed in the contact hole region A can be formed to have the same etch rate to inhibit the under-etch and over-etch from being generated, thereby providing superior patterns. The etch rate of the dummy line 232 disposed in the dummy region B may be different from that of the contact hole region A because of its relative positioning to the contact hole region such that it takes on the under-etch. However, since the dummy line 232 is not connected to the metal interconnection even if the under-etch is generated in the dummy line 232, yield of the semiconductor device is not affected.

Therefore, in a semiconductor device according to the embodiment, dummy patterns can be disposed around the dense contact holes to minimize a difference between the etching rates of the contact holes, thereby inhibiting the etching defect such as the under-etch or over-etch defects.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a metal interconnection on a substrate; and
a dielectric covering the metal interconnection, the dielectric comprising contact holes exposing a portion of the metal interconnection and dummy patterns surrounding the contact holes.

2. The semiconductor device according to claim 1, wherein the dummy patterns comprise a plurality of dummy contact holes, each dummy contact hole having the same size as the contact holes.

3. The semiconductor device according to claim 2, wherein at least one of the dummy contact holes is disposed on the metal interconnection without penetrating through the dielectric to expose the metal interconnection.

4. The semiconductor device according to claim 1, wherein the dummy patterns comprise a dummy line disposed along an edge region of the contact holes.

5. The semiconductor device according to claim 1, wherein each of the dummy patterns has a circular or square shape.

6. The semiconductor device according to claim 1, wherein a distance between each of the dummy patterns and a corresponding one or more of the contact holes adjacent thereto ranges from about 100 nm to about 140 nm.

7. A method of manufacturing a semiconductor device, the method comprising:
forming a metal interconnection on a substrate;
forming a dielectric on the metal interconnection;
forming a photoresist pattern on the dielectric; and
etching the dielectric using the photoresist pattern as an etch mask to form contact holes exposing the metal interconnection and dummy patterns at a region surrounding the contact holes.

8. The method according to claim 7, wherein etching the dielectric comprises:
performing a main etching process and performing an over etching process,
wherein performing the main etching process comprises using etching conditions in which a chamber pressure ranges from about 90 mT to about 120 mT, a source power ranges from about 200 W to about 800 W, a bias power ranges from about 1000 W to about 1500 W, a flow rate of argon ranges from about 150 sccm to about 350 sccm, a flow rate of C₄F₆ ranges from about 1 sccm to about 10 sccm, a flow rate of CH₂F₂ ranges from about 1 sccm to about 5 sccm, a flow rate of O₂ ranges from about 1 sccm to about 5 sccm, and a flow rate of N₂ ranges from about 100 sccm to about 250 sccm; and
wherein performing the over etching process comprises using etching conditions in which the chamber pressure ranges from about 100 mT to about 130 mT, the source power ranges from about 300 W to about 700 W, the bias power ranges from about 800 W to about 1500 W, the flow rate of argon ranges from about 200 sccm to about 300 sccm, the flow rate of C₄F₆ ranges from about 1 sccm to about 5 sccm, and the flow rate of N₂ ranges from about 80 sccm to about 150 sccm.

9. The method according to claim 8, wherein, during performing the over etching process, the C₄F₆:N₂ flow ratio is about 30:1.

10. The method according to claim 8, wherein, during performing the over etching process, the C₄F₆:N₂ flow ratio is less than 30:1.

11. The method according to claim 7, further comprising:
forming an anti-reflection layer on the dielectric, wherein the photoresist pattern is formed on the anti-reflection layer; and
etching the anti-reflection layer using the photoresist pattern as an etch mask to form an anti-reflection layer pattern, wherein the dielectric is etched using the photoresist pattern and the anti-reflection layer pattern as an etch mask.

12. The method according to claim 11, wherein etching the anti-reflection layer comprises using etching conditions in which a chamber pressure ranges from about 70 mT to about 110 mT, a source power ranges from about 100 W to about 500 W, a bias power ranges from about 0 W to about 100 W, a flow rate of argon ranges from about 200 sccm to about 400 sccm, a flow rate of CF₄ ranges from about 10 sccm to about 50 sccm, and a flow rate of O₂ ranges from about 2 sccm to about 10 sccm.

13. The method according to claim 7, wherein the dummy patterns comprise a plurality of dummy contact holes, each dummy contact hole having the same size as the contact holes.

14. The method according to claim 7, wherein the dummy patterns comprise a dummy line disposed along an edge region of the contact holes.

15. The method according to claim 7, wherein a distance between each of the dummy patterns and a corresponding one or more of the contact holes adjacent thereto ranges from about 100 nm to about 140 nm.
